(19) United States
(12) Patent Application Publication
(10) Pub. No.: US 2006/0185890 A1
(43) Pub. Date: Aug. 24, 2006

(54) AIR VOID VIA TUNING

(75) Inventor: Thomas Richard Robinson, Glenrothes (GB)

Correspondence Address: MARSTELLER & ASSOCIATES, P O BOX 803302, DALLAS, TX, 75380-3302, US

(73) Assignee: LITTON UK LIMITED, Gerrards Cross (GB)

(21) Appl. No.: 10/906,466

(22) Filed: Feb. 22, 2005

(51) Int. Cl. H05K 1/11

(52) U.S. Cl. 174/255; 174/262

(57) ABSTRACT

A wiring board (10) having reduced electromagnetic coupling between electronic devices includes a base board (12) that is adaptable to receive at least one electronic component (14) mounted on the base board (12). At least one hole or void (16) is formed in the base board (12). The hole (16) is separated from the selected electronic component (14) to be isolated against undesired electromagnetic radiation by a portion (18) of the base board (12).

### BACKGROUND OF THE INVENTION

1. Technical Field

The invention relates to the field of wiring boards for electronic devices, and more particularly to methods to suppress undesired electromagnetic radiation and coupling in components of the circuitry mounted on or formed with the wiring board.

2. Background Art

It is known to tune single vias by having a large hole on the upper layers of a base board or Printed Circuit Board (PCB) to accommodate a through hole connector and a narrower hole for the remaining layers to the bottom side.

Back drilling, which is the post process of drilling out the unused portion of the via barrel from the bottom side as close as is practicable to the signal trace, is also a known method used to reduce the effects of stubs on signal integrity. See FIG. 1.

Techniques are also known to address the problems of stray capacitance and creapage and clearance make use of larger clearances or separations between the signal via and surrounding ground planes of the base board. See FIG. 2.

Also known are methods that use a single rectangular, dog bone, oblong-round or oval anti-pad clearance to improve differential signal integrity. The oblong-round and rectangular variants are shown in FIGS. 3 and 4 for illustration purposes. An anti-pad generally is the area of copper or other conductive material that is etched away around a via or a plated through-hole on a power or ground plane, thereby preventing an electrical connection being made to that plane.

For example, U.S. Published Patent Number 20020179332 to Uematsu et al discloses a multi-layer wiring board including holes to control an impedance of the wiring patterns in the differential wiring. By forming the holes in a coaxial structure in the differential wiring, it becomes possible to control the impedance. Accordingly, the impedance of the holes can become equal to the impedance of the wiring patterns. Therefore, no reflection occurs between the wiring patterns and the holes. Hence, a degradation of the signal is prevented.

U.S. Published Patent Number 20040212971 to Iguchi discloses a pair of differential signal-use wirings wired to a first signal wiring layer. A pair of differential signal-use wirings wired to the second signal wiring layer are respectively connected via the first through holes. Additionally, the first through holes are both disposed inside the second through hole. Namely, the printed circuit board has a 2-core coaxial structure. In this manner, the printed circuit board has a structure where the first through holes, through which a pair of differential signals flows, are both surrounded by the single second through hole.

U.S. Pat. No. 4,628,343 to Komatsu teaches a semiconductor integrated circuit device formed on one semiconductor chip having a first circuit block or blocks and a second circuit block or blocks, which process a first signal and a second signal, respectively. The first and second signals are different in signal frequency or signal level from each other. A conductor layer showing substantially zero a.c. impedance is provided on a part of the semiconductor chip between the first and second circuit blocks. The conductor layer is preferably grounded with substantial zero impedance for an a.c. current. Moreover, an isolation region is formed in a part of the semiconductor chip between the first and second circuit blocks. This isolation region is directly connected to the conductor layer through at least one contact hole provided in a surface passivation film at a portion on the isolation region.

While clearly improving signal integrity none of the aforementioned known methods are capable of tuning the differential and single ended via structures to the same degree in terms of impedance, insertion and return loss for each and every signal layer in the PCB. Tuning problems are exacerbated by the trend towards ever-increased circuit density, layer count and subsequent PCB thickness, which is a feature of high technology backplanes.

While the above cited references introduce and disclose a number of noteworthy advances and technological improvements within the art, none completely fulfills the specific objectives achieved by this invention.

### SUMMARY OF INVENTION

The present invention addresses the problems caused in high-speed digital and RF system design where a number of electrical or electronic components are connected through printed circuit boards (PCB's) and connectors. Specifically, the present invention concerns tuning via structures for differential and single ended transmission lines, which form the primary juncture between the constituent elements. The present method substantially improves the main contributory factors for performance degradation, namely impedance discontinuity, insertion loss and return loss.

The present invention describes additional tuning potential from strategically inserting air voids in highly coupled areas of connector footprints in PCBs. The inserted air voids simultaneously increase the impedance while reducing the insertion and return losses through a virtual increase in separation between the electromagnetic (EM) radiating components incorporated on or into the circuit board. The effective material properties are improved by the present invention, or in other words, the present invention reduces the effective dielectric constant and loss tangent. Such air voids could for example be created using non-plated via holes or milled slots in the PCB.

In accordance with the present invention, a wiring board and method of manufacture is disclosed. The electronics wiring board having reduced electromagnetic coupling between electronic devices includes a base board that is adaptable to receive at least one electronic component mounted on the base board. At least one hole or void is formed in the base board. The hole is separated from the selected electronic component to be isolated against undesired electromagnetic radiation by at least a portion of the wiring board.

The present invention utilizes prior art methods as a baseline for via tuning, the present method enhances the via constructs' electrical performance in terms of impedance, insertion loss and return loss.

The present invention provides more freedom and opportunity for via tuning regardless of the vias penultimate use e.g. interconnection type (Digital or RF), connector type (solder, press-fit or surface mount). Furthermore, the present invention allows for improved via tuning regardless of the PCB material selected. For example, the present technique can be applied to exotic high performance materials such as Rogers 4350 or an industry standard material such as FR4.

The present method of air void tuning for base boards is also particularly useful to a via pattern determined by a connector since if the via were “free standing,” then there would normally be ample space to adjust any anti-pads used in the configuration.

These and other objects, advantages and features of this invention will be apparent from the following description taken with reference to the accompanying drawings, wherein is shown the preferred embodiments of the invention.

### BRIEF DESCRIPTION OF DRAWINGS

A more particular description of the invention briefly summarized above is available from the exemplary embodiments illustrated in the drawings and discussed in further detail below. Through this reference, it can be seen how the above cited features, as well as others that will become apparent, are obtained and can be understood in detail. The drawings nevertheless illustrate only typical, preferred embodiments of the invention and are not to be considered limiting of its scope as the invention may admit to other equally effective embodiments.

FIG. 1 is a cross sectional view of a printed circuit board using the prior art technique of back drilling.

FIG. 2 is a plan or top view of a base board showing a known technique using larger clearances or separations between the signal via and surrounding ground planes.

FIG. 3 is a plan or top view of a base board showing a known technique using oblong-round anti-pad clearance.

FIG. 4 is a plan or top view of a base board showing a known technique using a rectangular variant for the anti-pad clearance.

FIG. 5 is a plan or top view of a base board showing the present invention using a cylindrical air void.

FIG. 6 is a plan or top view of a base board showing an alternative embodiment of the present invention using an air void having an oblong-round or slotted cross-section.

FIG. 7 is a plan or top view of a base board showing yet another alternative embodiment of the present invention with three oblong-round air void slots.

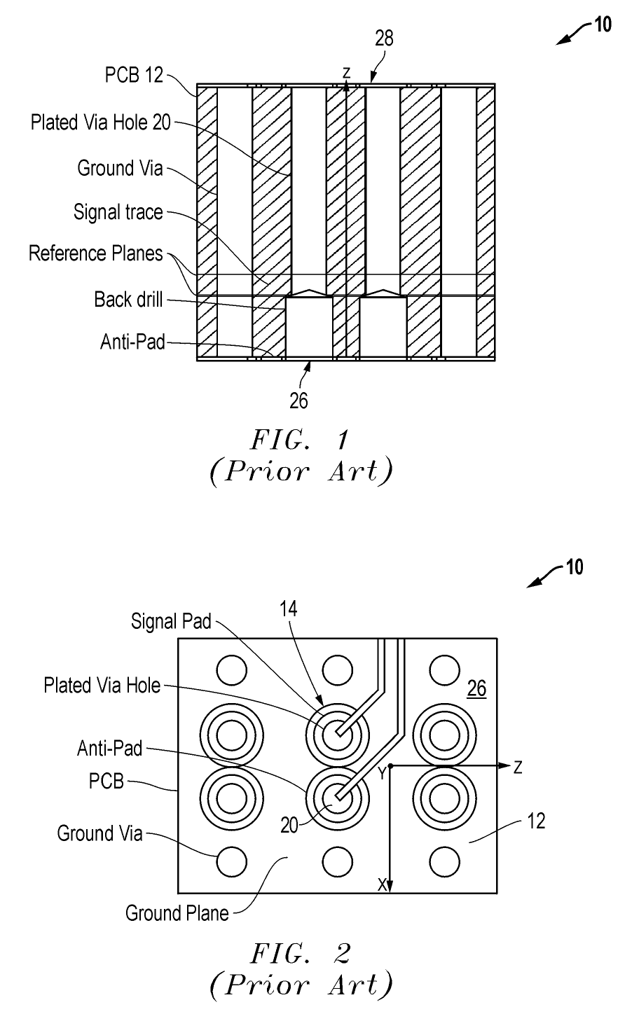

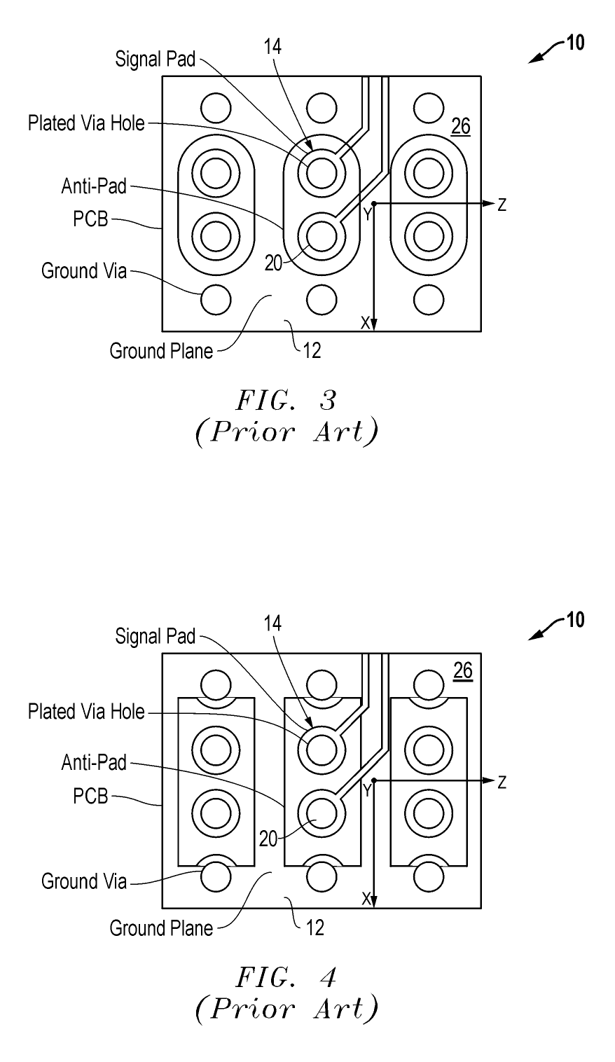

### DETAILED DESCRIPTION

So that the manner in which the above recited features, advantages, and objects of the present invention are attained can be understood in detail, more particular description of the invention, briefly summarized above, may be had by reference to the embodiment thereof that is illustrated in the appended drawings. In all the drawings, identical numbers represent the same elements.

In the present invention a wiring board 10 and method of manufacture is disclosed. The electronics wiring board 10 having reduced electromagnetic coupling between electronic devices includes a base board 12 that is adaptable to receive at least one electronic component 14 mounted on the base board 12. At least one hole or void 16 is formed in the base board 12 in the proximity of the electronic component 14 to be isolated. The hole 16 is separated from the selected electronic component 14 to be isolated against undesired electromagnetic radiation by a portion or segment 18 of the base board or PCB 12.

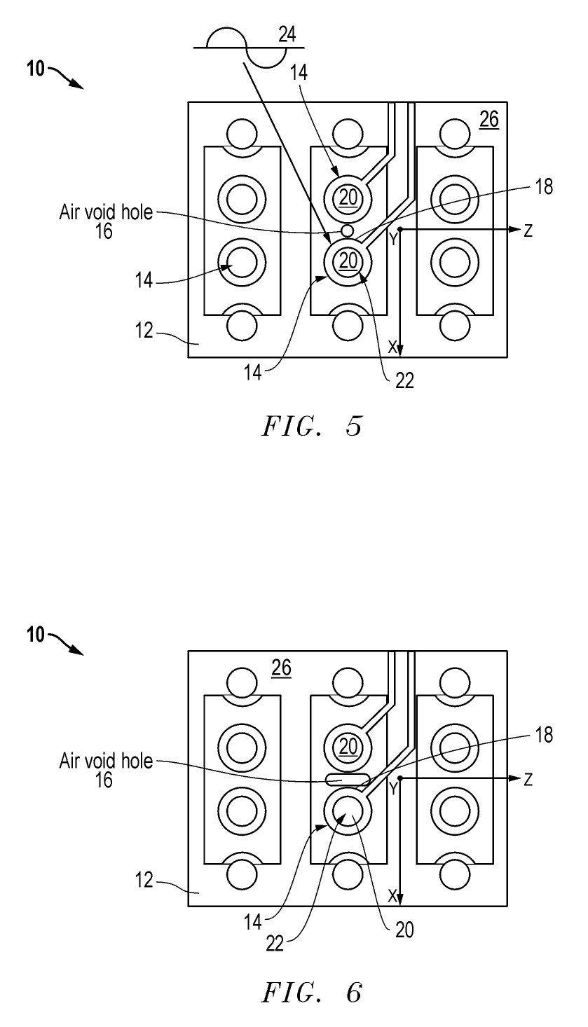

Referring to FIG. 5, a single cylindrical air void 16 is created and located between a pair of vias 20 with an electromagnetic conductor 22 carrying a differential signal 24. The air void, which is shown as a first embodiment in FIG. 5 as a circular hole or cylinder in the plan or top view of the PCB, optionally traverses all the way through the PCB from a top surface 26 to a bottom surface 28 of the base board 12.

The air void 16 preferably is not to be filled with any insulator material creating an empty space or void within the base board 12, although any known insulator may be used to replace the part of the base board 12 removed to form the air void 16.

The configuration shown in FIG. 5 generally yields improved results in terms of differential impedance, insertion and return loss, over the known art described above.

A second alternative embodiment of the present invention shown in FIG. 6 uses a single oblong-round or “slotted” air void 16 between the pair of vias 20 carrying the differential signal 24. The air void 16, seen as an elongated slot in a top or plan view of the base board or PCB, optionally traverses all the way through the PCB from the top to bottom surfaces or layers.

The configuration of the second alternative embodiment using an oblong-round or slotted air void 16 improves the differential impedance, insertion and return loss even over that of the first configuration of FIG. 5.

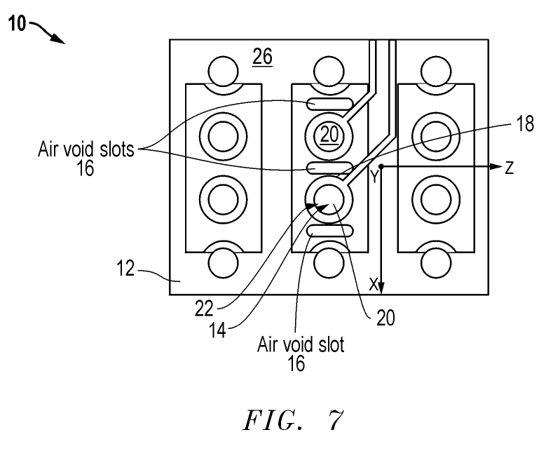

A third alternative embodiment of the present method uses two more oblong-round or slotted air voids 16 with one on either side of the via 20 pair carrying the differential signal as shown in FIG. 7. The air voids 16, seen as elongated slots in the top or plan view of the PCB in FIG. 7, optionally traverse all the way through the PCB from the top to bottom surfaces 26 and 28, respectively.

The third alternative embodiment shown in FIG. 7 generally makes a further improvement in terms of differential impedance, insertion and return loss over the first and second alternative configurations shown in FIGS. 5 and 6 respectively.

Depending on the specific application or design of the PCB, the electromagnetic conductive vias 20 may traverse the entire base board or PCB 12 cross section, or in other words, from the top layer 26 or surface to the bottom surface 28 or signal layer.

A plurality of air voids 16 may be formed in the base board 12 at selected locations to reduce undesired electromagnetic radiation as long as the physical integrity of the base board 12 is maintained. Further, the size and shape of each air void 16 may be selected to achieve the desired insulation from the undesired EM radiation.

The present air void via tuning (AVVT) method can take a number of forms, some of which will be governed by the physical topology of the PCB 12 and others by the processes of manufacture and costs. For simplicity, a post processing version of implementation may use mechanical or laser drilling. There is no reason beyond current manufacturing limitations and the PCB topology as to why the air voids 16 of the present invention cannot adopt any shape at any point in the vertical axis. Also, the air voids 16 do not have to be formed completely extending between the opposing upper and lower surfaces 26 and 28 respectively, but may extend only a portion of the distance between the two opposing surfaces depending on the choice of the designer and the conditions specific to the printed circuit board layout.

A further embodiment may include sequential lamination techniques for printed circuit boards 12 to produce 3-dimensional air voids 16 on a surface of the PCB or within the PCB itself between the upper and lower surfaces of the PCB or base board to further enhance tuning potential. It may be desirable for a specific application that an Air Void Via 16 may only traverse a few layers of a multi-layer PCB, or may be contained wholly within the PCB cross-section between the opposing upper and lower surfaces 26 and 28 respectively.

Although inherently simpler to tune than differential via topologies, the present invention applies equally well to single ended via constructs. Applications may include, by way of example, single via topologies in densely packed areas where coupling is high or where insertion loss and return loss are critical to system performance.

The foregoing disclosure and description of the invention are illustrative and explanatory thereof, and various changes in the size, shape and materials, as well as in the details of the illustrated construction may be made without departing from the spirit of the invention.

1. A writing board for electronic devices comprising:
a base board adaptable to receive at least one electronic component mounted on the base board; and,
at least one non-plated hole formed in the base board; the non-plated hole being separated from the selected electronic component to be isolated against undesired electromagnetic radiation.

2. The invention of claim 1 wherein the hole and the selected electronic component are separated by a portion of the base board.

3. The invention of claim 1 wherein the hole extends between an upper surface of the base board and a lower surface of the base board.

4. The invention of claim 1 wherein the hole forms a cylindrical void in the base board.

5. The invention of claim 1 wherein a cross-section of the hole is an elongated slot.

6. The invention of claim 1 wherein the hole is formed free of any added filling materials.

7. The invention of claim 1 wherein the electronic component is a via formed in the base board and the via contains an electromagnetic conductor and the hole is in desired proximity to the via.

8. The invention of claim 1 wherein the base board is a multi-layer wiring board.

9. The invention of claim 1 wherein the hole is formed in the base board interstitially between a pair of vias carrying a differential signal.

10. (canceled)

11. (canceled)

12. (canceled)

13. (canceled)

14. (canceled)

15. (canceled)

16. (canceled)

17. (canceled)

18. (canceled)
